(19) United States
(12) Patent Application Publication
(10) Pub. No.: US 2007/0113978 A1
(43) Pub. Date: May 24, 2007

(54) Plasma processing apparatus and method

(75) Inventors: Nobuo Ishii, Higashinada-ku (JP); Kibatsu Shinohara, Yokohama-shi (JP)

Correspondence Address: CROWELL & MORING LLP;INTELLECTUAL PROPERTY GROUP, P.O. BOX 14300, WASHINGTON, DC, 20044-4300, US

(73) Assignee: TOKYO ELECTRON LIMITED, TOKYO (JP)

(21) Appl. No.: 10/544,632

(22) PCT Filed: Feb. 4, 2004
(86) PCT No.: PCT/JP04/01135

§ 371 Date: Aug. 15, 2006

(30) Foreign Application Priority Data
Feb. 7, 2003 (JP) 2003-030914

(51) Int. Cl. C23F 1/00; C23C 16/00

(52) U.S. Cl. 156/345.42; 118/723 MW

(57) ABSTRACT

A plasma processing apparatus includes a stage (3) on which an object (4) to be processed is to be placed, a vessel (1) which houses the stage, a conductive plate (24) which is arranged to oppose the stage, an antenna element (27) which is formed on the conductive plate, a waveguide member (22, 23) which constitutes, together with the conductive plate, a waveguide (21) which guides a high-frequency electromagnetic field to be supplied to the vessel through the antenna element, and cooling means (12, 31-35) for cooling the conductive plate. The conductive plate is cooled using the cooling means, so that a temperature change caused by heat generated by the conductive plate is suppressed. This can prevent the conductive plate from being deformed by the heat to change antenna characteristics. Hence, a distribution of a plasma (P) generated in the vessel is not affected by the change in the antenna characteristics, and the object to be processed arranged in the vessel can be processed uniformly.

### TECHNICAL FIELD

The present invention relates to a plasma processing apparatus and method and, more particularly, to a plasma processing apparatus and method which generate a plasma by using a high-frequency electromagnetic field to process an object to be processed such as a semiconductor, LCD (liquid crystal display), organic EL (electro luminescent panel), or the like.

### BACKGROUND ART

In the manufacture of a semiconductor device or flat panel display, plasma processing apparatuses are used often to perform processes such as formation of an oxide film, crystal growth of a semiconductor layer, etching, and ashing. Among the plasma processing apparatuses, a high-frequency plasma processing apparatus is available which supplies a high-frequency electromagnetic field into a processing vessel to ionize and dissociate a gas in the processing vessel, thus generating a plasma. The high-frequency plasma processing apparatus can perform a plasma process efficiently since it can generate a high-density plasma at a low pressure.

FIG. 10 is a view showing the overall structure of a conventional high-frequency plasma processing apparatus. This plasma processing apparatus has a processing vessel 101 having an upper opening. A stage 103 is fixed to the central portion of the bottom surface of the processing vessel 101. A substrate 104 is placed on the upper surface of the stage 103. Exhaust ports 105 for vacuum evacuation are formed in the peripheral portion of the bottom surface of the processing vessel 101. A gas introducing nozzle 106 is arranged in the side wall of the processing vessel 101.

The upper opening of the processing vessel 101 is closed with a dielectric plate 107. A radial line slot antenna (to be abbreviated as RLSA hereinafter) 113 is disposed above the dielectric plate 107. A high-frequency power supply 111 which generates a high-frequency electromagnetic field is connected to the RLSA 113 through a waveguide 112. The outer surfaces of the dielectric plate 107 and RLSA 113 are covered with a shield material 109 which prevents leak of the high-frequency electromagnetic field.

The RLSA 113 has two parallel conductive plates 122 and 124 which form a radial waveguide 121, and a conductive ring 123 which connects the edge portions of the two conductive plates 122 and 124. The conductive plate 122 which serves as the upper surface of the radial waveguide 121, and the conductive ring 123 are formed integrally, and the conductive plate 124 which serves as the lower surface of the radial waveguide 121 is fixed to the lower surface of the conductive ring 123 with a plurality of screws 125. An opening 126 to be connected to the waveguide 112 is formed at the central portion of the conductive plate 122. The high-frequency electromagnetic field is introduced into the radial waveguide 121 through the opening 126. A plurality of slots 127, through which the high-frequency electromagnetic field propagating in the radial waveguide 121 is supplied into the processing vessel 101 through the dielectric plate 107, are formed in the conductive plate 124. These slots 127 form a slot antenna, and accordingly the conductive plate 124 which has the slots 127 is called the antenna surface of the RLSA 113.

In the plasma processing apparatus with the above structure, when the high-frequency power supply 111 is driven to generate a high-frequency electromagnetic field, the high-frequency electromagnetic field is introduced into the radial waveguide 121 through the waveguide 112. The high-frequency electromagnetic field introduced into the radial waveguide 121 is gradually supplied into the processing vessel 101 through the plurality of slots 127 which are formed in the antenna surface 124 corresponding to the lower surface of the radial waveguide 121, while it propagates radially from the central portion toward the peripheral portion of the radial waveguide 121. In the processing vessel 101, a gas introduced from the nozzle 106 is ionized and dissociated by the supplied high-frequency electromagnetic field to form a plasma P, thus processing the substrate 104 (for example, see Japanese Patent Laid-Open No. 2002-217187).

When the high-frequency power supply 111 is driven to introduce the high-frequency electromagnetic field into the radial waveguide 121 of the RLSA 113, a current occurs in the antenna surface 124 corresponding to the lower surface of the radial waveguide 121, and the resistance of the conductive plate 124 generates the Joule heat. Although the antenna surface 124 is screwed to the lower surface of the conductive ring 123 of the RLSA 113, the antenna surface 124 is not in tight contact with the lower surface of the conductive ring 123. Thus, the heat generated in the antenna surface 124 is not easily transferred to the waveguide member including the conductive ring -123 and conductive plate 122. As the antenna surface 124 is in contact with none of the processing vessel 101 and shield material 109, the heat generated in the antenna surface 124 is not transferred to them. Hence, the heat stays in the antenna surface 124 to sometimes heat it to a high temperature of 100° C. or more. When the antenna surface 124 is heated to such a high temperature, it deforms, although a little, and the antenna characteristics change. When the antenna characteristics change and the dose, radiation direction, and the like of the high-frequency electromagnetic field change, the distribution of the plasma which is generated in the processing vessel 101 by the high-frequency electromagnetic field changes. Then, the substrate 104 on the stage 103 cannot be processed uniformly.

### DISCLOSURE OF INVENTION

The present invention has been made to solve the above problems, and has as its object to suppress a change in antenna characteristics which is caused by a temperature change of the antenna surface.

In order to achieve the above object, according to the present invention, there is provided a plasma processing apparatus characterized by comprising a stage on which an object to be processed is to be placed, a vessel which houses the stage, a conductive plate which is arranged to oppose the stage, an antenna element which is formed on the conductive plate, a waveguide member which constitutes, together with the conductive plate, a waveguide which guides a high-frequency electromagnetic field to be supplied to the vessel through said antenna element, and cooling means for cooling the conductive plate.

According to the present invention, there is also provided a plasma processing method characterized by comprising the steps of guiding a high-frequency electromagnetic field to a waveguide which includes a waveguide member and conductive plate, supplying the high-frequency electromagnetic field into a vessel through an antenna element formed in the conducive plate to generate a plasma in the vessel and cooling the conductive plate, and processing an object to be processed arranged in the vessel by using the plasma.

### BRIEF DESCRIPTION OF DRAWINGS

FIG. 1 is a view showing the overall structure of a plasma processing apparatus according to the first embodiment of the present invention;

FIG. 2 is a plan view of a conductive plate which serves as the upper surface of a radial waveguide;

FIG. 3 is a view showing the structure of part of a modification of the plasma processing apparatus shown in FIG. 1;

FIG. 4 is a view showing the structure of part of a plasma processing apparatus according to the second embodiment of the present invention;

FIG. 5 is a view showing the structure of part of a plasma processing apparatus according to the third embodiment of the present invention;

FIG. 6 is a view showing the lower surface of a pipe line;

FIG. 7 is a view showing the structure of part of a plasma processing apparatus according to the fourth embodiment of the present invention;

FIG. 8 is a view showing the structure of part of a plasma processing apparatus according to the fifth embodiment of the present invention;

FIG. 9 is a view showing the structure of part of a modification of the plasma processing apparatus shown in FIG. 8; and

FIG. 10 is a view showing the overall structure of a conventional high-frequency plasma processing apparatus.

### BEST MODE FOR CARRYING OUT THE INVENTION

The embodiments of the present invention will be described in detail with reference to the drawings.

### First Embodiment

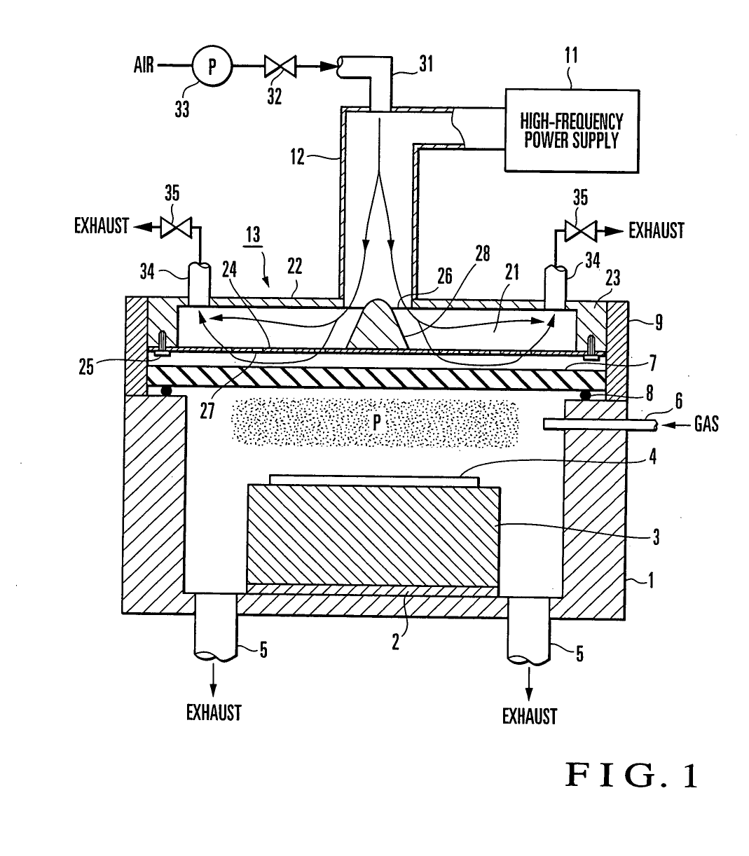

FIG. 1 is a view showing the overall structure of a plasma processing apparatus according to the first embodiment of the present invention. This plasma processing apparatus has a bottomed cylindrical processing vessel 1 having an upper opening. A stage 3 is fixed to the central portion of the bottom surface of the processing vessel 1 through an insulating plate 2. A substrate 4 such as a semiconductor, LCD or the like is placed as an object to be processed on the upper surface of the stage 3. Exhaust ports 5 for vacuum evacuation are formed in the peripheral portion of the bottom surface of the processing vessel 1. A gas introducing nozzle 6 through which a gas is to be introduced into the processing vessel 1 is arranged in the side wall of the processing vessel 1. For example, when the plasma processing apparatus is to be used as an etching apparatus, a plasma gas such as Ar and an etching gas such as CF₄ are introduced through the nozzle 6.

The upper opening of the processing vessel 1 is closed with a dielectric plate 7 so, while a high-frequency electromagnetic field is introduced through the upper opening, a plasma P generated in the processing vessel 1 does not leak outside. A seal member 8 such as an O-ring is interposed between the upper surface of the side wall of the processing vessel 1 and the lower surface of the peripheral portion of the dielectric plate 7 to ensure the hermeticity in the processing vessel 1.

An RLSA 13 of an electromagnetic field supply device which supplies a high-frequency electromagnetic field into the processing vessel 1 is disposed above the dielectric plate 7. The RLSA 13 is isolated from the processing vessel 1 by the dielectric plate 7 and accordingly protected from the plasma P. The outer surfaces of the dielectric plate 7 and RLSA 13 are covered with a shield material 9 annularly arranged on the side wall of the processing vessel 1. Thus, the high-frequency electromagnetic field supplied from the RLSA 13 into the processing vessel 1 will not leak outside.

The electromagnetic field supply device has a high-frequency power supply 11 which generates a high-frequency electromagnetic field having a predetermined frequency within the range of, e.g., 0.9 GHz to ten-odd GHz, the RLSA 13 described above, and a waveguide 12 which connects the high-frequency power supply 11 and RLSA 13. Although not shown, at least one of a circular polarization converter and load matching unit may be provided to the waveguide 12.

The RLSA 13 has two parallel circular conductive plates 22 and 24 which form a radial waveguide 21, and a conductive ring 23 which connects the edge portions of the two conductive plates 22 and 24 so that they are shielded. The conductive plate 22 which serves as the upper surface of the radial waveguide 21, and the conductive ring 23 are formed integrally, and the conductive plate 24 which serves as the lower surface of the radial waveguide 21 is fixed to the lower surface of the conductive ring 23 with a plurality of screws 25. An opening 26 to be connected to the waveguide 12 is formed at the central portion of the conductive plate 22 which serves as the upper surface of the radial waveguide 21. A high-frequency electromagnetic field is introduced into the radial waveguide 21 through the opening 26. A plurality of slots 27, through which the high-frequency electromagnetic field propagating in the radial waveguide 21 is to be supplied into the processing vessel 1 through the dielectric plate 7, are formed in the conductive plate 24 which serves as the lower surface of the radial waveguide 21. These slots 27 form a slot antenna (antenna element). Thus, the conductive plate 24 where the slots 27 are formed is called the antenna surface of the RLSA 13.

A bump 28 is provided to the central portion on the antenna surface 24. The bump 28 is formed to have a substantially circular conical shape projecting toward the opening 26 of the conductive plate 22, and its distal end is rounded spherically. The bump 28 can be made of either a conductor or dielectric. With the bump 28, a change in impedance from the waveguide 12 to the radial waveguide 21 is moderated, and accordingly the reflection of the high-frequency electromagnetic field at the connecting portion of the waveguide 12 and radial waveguide 21 can be suppressed.

In this structure, when the high-frequency power supply 11 is driven to generate a high-frequency electromagnetic field, the high-frequency electromagnetic field is introduced into the radial waveguide 21 through the waveguide 12. The high-frequency electromagnetic field introduced into the radial waveguide 21, while propagating radially from the central portion toward the peripheral portion of the radial waveguide 21, is gradually supplied into the processing vessel 1 through the plurality of slots 27 formed in the antenna surface 24 which corresponds to the lower surface of the radial waveguide 21. In the processing vessel 1, the supplied high-frequency electromagnetic field ionizes and dissociates the plasma gas introduced through the nozzle 6 to generate the plasma P, thus processing the substrate 4.

When the high-frequency electromagnetic field is introduced into the radial waveguide 21 of the RLSA 13, the antenna surface 24 which corresponds to the lower surface of the radial waveguide 21 is heated by the Joule heat. To cool the heated antenna surface 24, a cooling means is provided in this embodiment. The cooling means includes a refrigerant supplying means for supplying a refrigerant into the radial waveguide 21, and a refrigerant discharging means for discharging the refrigerant, circulating in the radial waveguide 21, outside the radial waveguide 21.

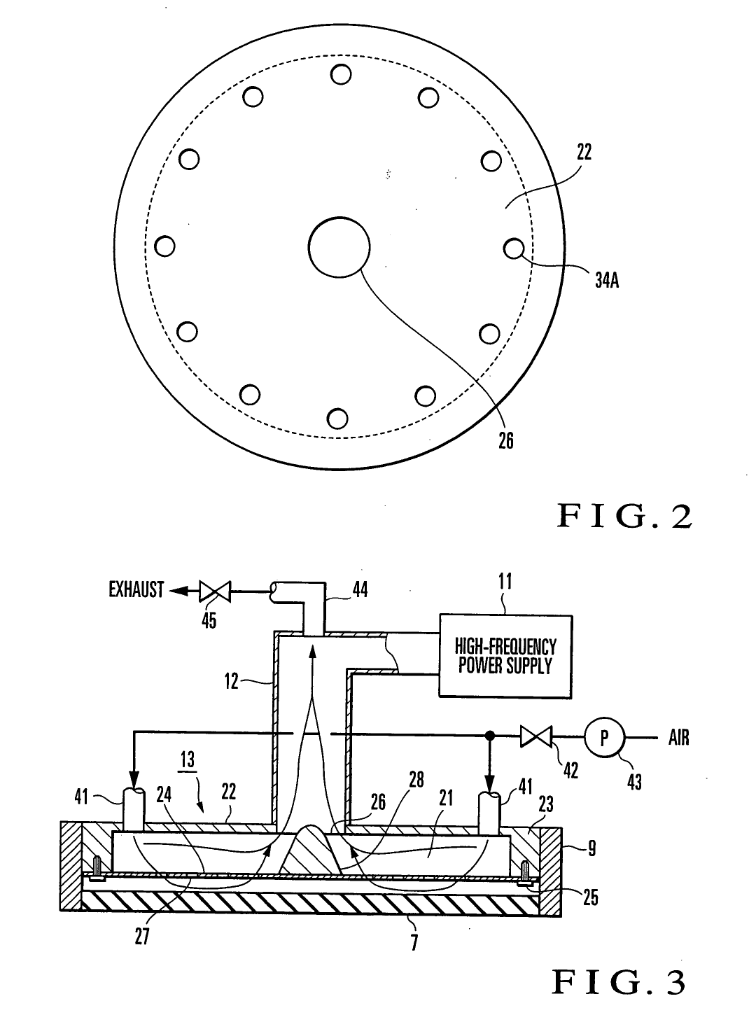

More specifically, the refrigerant supplying means includes the waveguide 12, a refrigerant supply channel 31 which opens to the waveguide 12, and a supply opening/closing valve 32 and refrigerant pump 33 which are provided to the refrigerant supply channel 31. The refrigerant discharging means includes refrigerant discharge channels 34 which open to the radial waveguide 21, and discharge opening/closing valves 35 respectively provided to the refrigerant discharge channels 34. As shown in FIG. 2, a plurality of openings 34A of the refrigerant discharge channels 34 are equidistantly formed in the peripheral portion of the conductive plate 22 which serves as the upper surface of the radial waveguide 21. In FIG. 1, the driving operation of the refrigerant pump 33 and the opening/closing operation of the opening/closing valves 32 and 34 are controlled by a controller (not shown). As the refrigerant, normal-temperature air is used.

When the opening/closing valves 32 and 34 are opened and the pump 33 sends air, the air is introduced into the waveguide 12 through the refrigerant supply channel 31. The air flows through the waveguide 12 and is supplied into the radial waveguide 21 through the opening 26 at the central portion of the conductive plate 22 which serves as the upper surface of the radial waveguide 21. The air supplied into the radial waveguide 21 spreads from the central portion toward the peripheral portion of the radial waveguide 21. Also, the air partly flows through the plurality of slots 27 formed in the antenna surface 24 and spreads in the space between the antenna surface 24 and dielectric plate 7 in the same manner from the central portion toward the peripheral portion. The air which has reached the peripheral portion is discharged outside the radial waveguide 21 through the plurality of refrigerant discharge channels 34 which open to the peripheral portion of the conductive plate 22 serving as the upper surface of the radial waveguide 21. Since the seal member 8 is interposed between the lower surface of the peripheral portion of the dielectric plate 7 and the upper surface of the side wall of the processing vessel 1, the air does not enter the processing vessel 1.

While the antenna surface 24 is cooled as the Joule heat that heats the antenna surface 24 shifts to air having a lower temperature than that of the antenna surface 24, simultaneously, the air is heated on the other hand. According to this embodiment, the heated air is discharged from the radial waveguide 21, and low-temperature air is introduced into the radial waveguide 21, to maintain the temperature difference between the antenna surface 24, and air, thus promoting heat shift from the antenna surface 24 to the air. As a result, the antenna surface 24 can be cooled efficiently to suppress a temperature change in it.

When the temperature change in the antenna surface 24 is suppressed in this manner, a change in antenna characteristics can be prevented. Hence, the distribution of the plasma generated in the processing vessel 1 is not changed by the influence of the change in antenna characteristics, and the substrate 4 arranged on the stage 3 can be processed uniformly.

In the plasma processing apparatus shown in FIG. 1, the refrigerant supply channel 31 is connected to the waveguide 12, and the refrigerant discharge channels 34 are connected to the radial waveguide 21, but this connection can be made in an opposite manner. More specifically, as shown in FIG. 3, a refrigerant supply channel 41 may be branched and connected to the radial waveguide 21, and a refrigerant discharge channel 44 may be connected to the waveguide 12. In this case, in the same manner as in FIG. 2, the openings of the refrigerant supply channel 41 are formed equidistantly in the peripheral portion of the conductive plate 22 which serves as the upper surface of the radial waveguide 21. A common supply opening/closing valve 42 and refrigerant pump 43 are provided to the refrigerant supply channel 41. Also, a discharge opening/closing valve 45 is provided to the refrigerant discharge channel 44.

So far a case has been described in which either the refrigerant supply channel 31 or refrigerant discharge channels 34 are connected to the waveguide 12 and the remaining channel 31 or channels 34 are connected to the radial waveguide 21. Alternatively, both the refrigerant supply channel 31 and refrigerant discharge channels 34 may be connected to the radial waveguide 21. In this case, the opening of the refrigerant supply channel 31 and the openings of the refrigerant discharge channels 34 are formed at separate positions.

### Second Embodiment

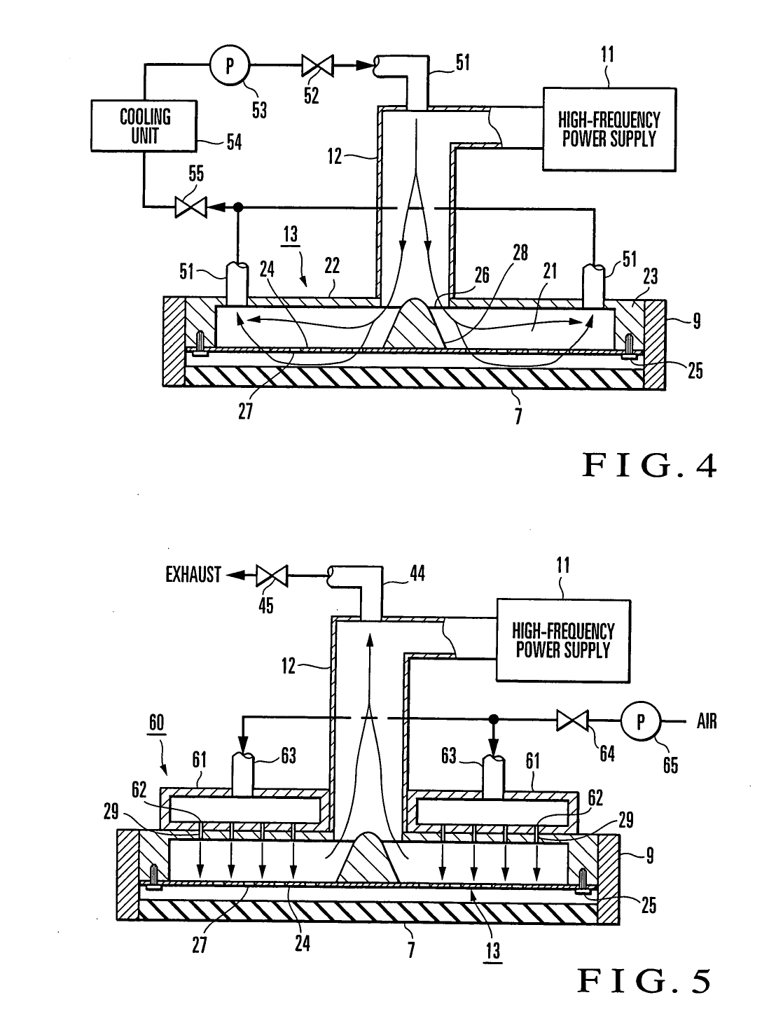

FIG. 4 is a view showing the structure of part of a plasma processing apparatus according to the second embodiment of the present invention. In FIG. 4, constituent elements such as a processing vessel 1 are not shown.

The plasma processing apparatus according to this embodiment has a refrigerant flow channel 51 formed by connecting the refrigerant supply channel of a refrigerant supplying means and the refrigerant discharge channel of a refrigerant discharging means. The supply port of the refrigerant flow channel 51 opens to a waveguide 12, and its plurality of discharge ports equidistantly open to the peripheral portion of a conductive plate 22 which serves as the upper surface of a radial waveguide 21, in the same manner as in FIG. 2. A supply opening/closing valve 52 is provided to the supply port side of the refrigerant flow channel 51, and a discharge opening/closing valve 55 is provided to its discharge port side. A refrigerant pump (refrigerant feeding means) 53 which feeds out a refrigerant and a cooling unit (refrigerant cooling means) 54 which cools the heated refrigerant to the original temperature are provided between the two opening/closing valves 52 and 55. As the refrigerant, other than air, an inert gas such as N₂ can be used.

With this structure, the refrigerant flow channel 52, waveguide 12, and radial waveguide 21 form a closed channel. While circulating in this closed channel, the refrigerant deprives an antenna surface 24 of heat to cool it. Thereafter, the cooling unit 54 takes away from the refrigerant the heat that the refrigerant took away from the antenna surface 24 so the refrigerant restores the original temperature. Therefore, the antenna surface 24 can be cooled repeatedly using the same refrigerant.

In the same manner as in FIG. 3, supply ports for the refrigerant flow channel 51 may be formed in the conductive plate 22 which serves as the upper surface of the radial waveguide 21, and a discharge port for it may be formed in the waveguide 12, so the refrigerant is circulated in the opposite direction.

In the first and second embodiments described above, a liquid such as cooling water may be used as the refrigerant. In this case, the plasma processing apparatus must be formed such that the refrigerant does not leak from it.

### Third Embodiment

FIG. 5 is a view showing the structure of part of a plasma processing apparatus according to the third embodiment of the present invention. In FIG. 5, constituent elements such as a processing vessel 1 are not shown.

In the plasma processing apparatus according to this embodiment, a refrigerant spray member 60 which sprays a refrigerant toward an antenna surface 24 is disposed on a conductive plate 22 of an RLSA 13. The refrigerant spray member 60 has an annular pipe line 61 which surrounds a waveguide 12. The inner radius of the pipe line 61 is substantially equal to the radius of the waveguide 12, and its outer radius is substantially equal to the radius of a radial waveguide 21.

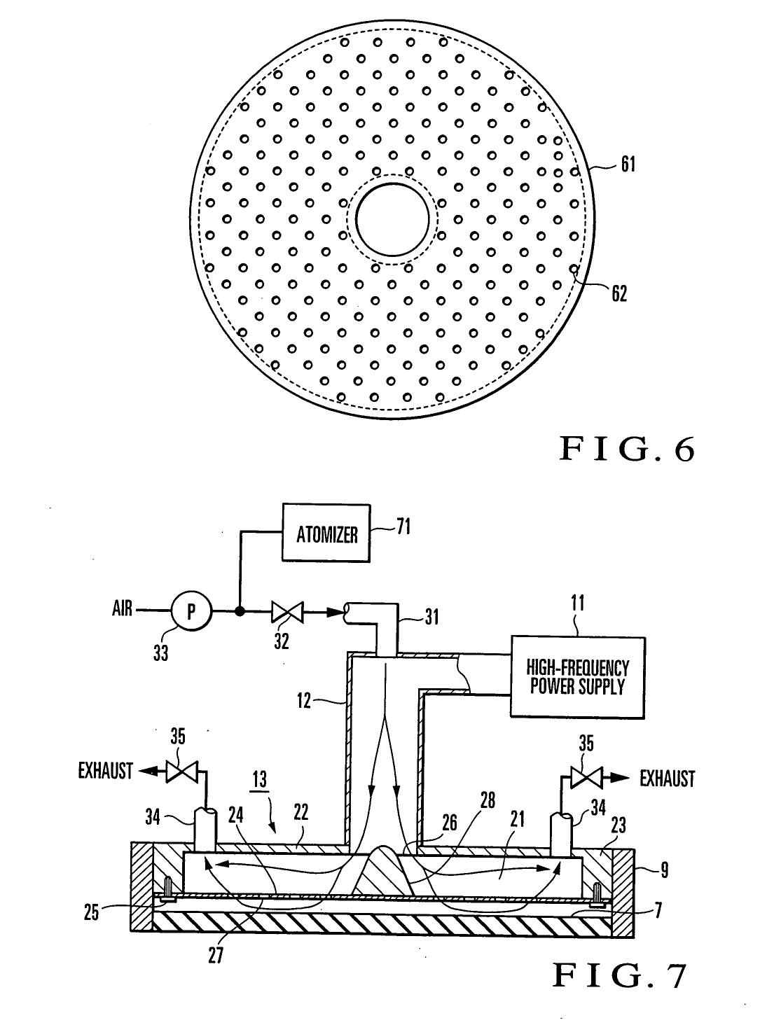

As shown in FIGS. 5 and 6, a plurality of small-diameter through holes 62 are formed in the entire area of the lower surface of the pipe line 61. A plurality of small-diameter through holes 29 are also formed in the conductive plate 22 of the RLSA 13 in contact with the lower surface of the pipe line 61, at positions corresponding to the through holes 62 of the pipe line 61. The interiors of the pipe line 61 and radial waveguide 21 communicate with each other through the through holes 62 and 29.

A refrigerant supply channel 63 opens to the upper surface of the pipe line 61. The refrigerant supply channel 63 is provided with a supply opening/closing valve 64 and refrigerant pump 65.

A refrigerant discharge channel 44 opens to the waveguide 12, in the same manner as in FIG. 3, and a discharge opening/closing valve 45 is provided to the refrigerant discharge channel 44.

As the refrigerant, normal-temperature air is used.

In the refrigerant spray member 60 as described above, when the pump 65 feeds air to the pipe line 61 to increase the pressure in the pipe line 61 to be sufficiently higher than the pressure in the radial waveguide 21, the air is sprayed from the pipe line 61 toward the antenna surface 24 of the RLSA 13 through the through holes 62 and 29. The air introduced into the radial waveguide 21 adiabatically expands instantaneously to decrease its temperature. The temperature-decreased air abuts against the antenna surface 24 directly to cool it efficiently.

A refrigerant circulating channel may be formed in the same manner as in the second embodiment, and an inert gas may be used as the refrigerant.

### Fourth Embodiment

FIG. 7 is a view showing the structure of part of a plasma processing apparatus according to the fourth embodiment of the present invention. In FIG. 7, constituent elements such as a processing vessel 1 are not shown.

As a refrigerant, the plasma processing apparatus according to this embodiment uses air containing an atomized liquid agent. More specifically, in the first embodiment, an atomizer 71 which atomizes a liquid agent and emits it is connected to the refrigerant supply channel 31.

When the atomizer 71 is driven, the atomized liquid agent is dispensed to the refrigerant supply channel 31 and mixed with air flowing in the refrigerant supply channel 31. The mixture is then supplied to a waveguide 12. While the air containing the atomized liquid agent spreads from the waveguide 12 into a radial waveguide 21, when the atomized liquid agent attaches to an antenna surface 24, during evaporation, it deprives the antenna surface 24 of the heat of evaporation. Thus, the antenna surface 24 can be cooled efficiently.

An example of the liquid agent can include water, but a liquid agent having a larger heat of evaporation may be used. Also, an inert gas may be used in place of air. If an atomizer 71 is connected to the refrigerant supply channel 41 in FIG. 3, the same operation and effect can be obtained.

### Fifth Embodiment

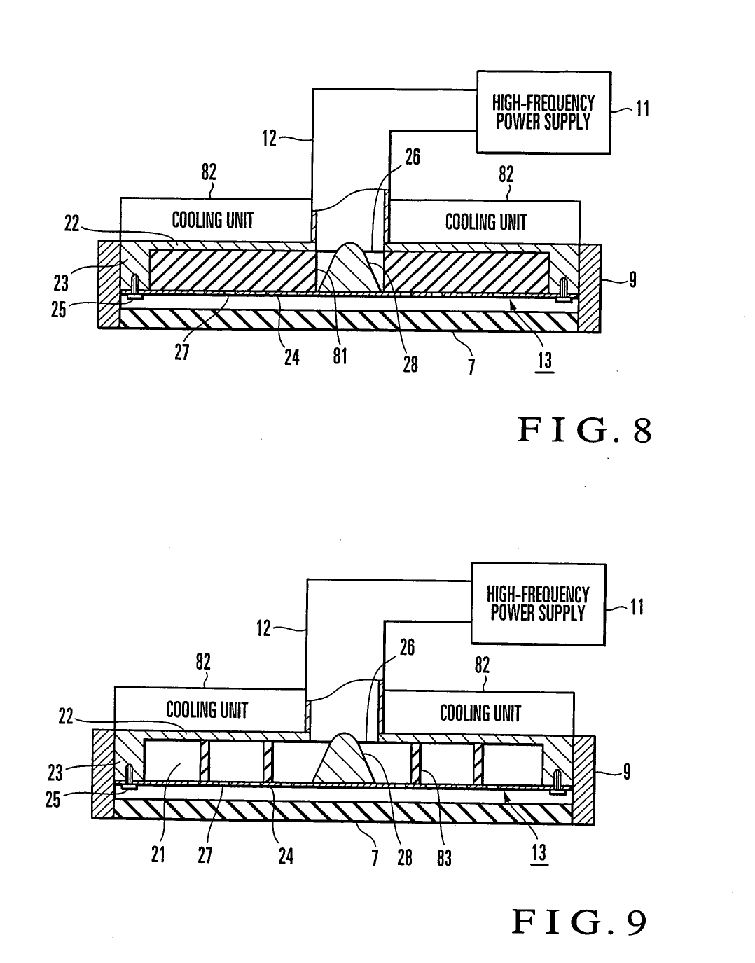

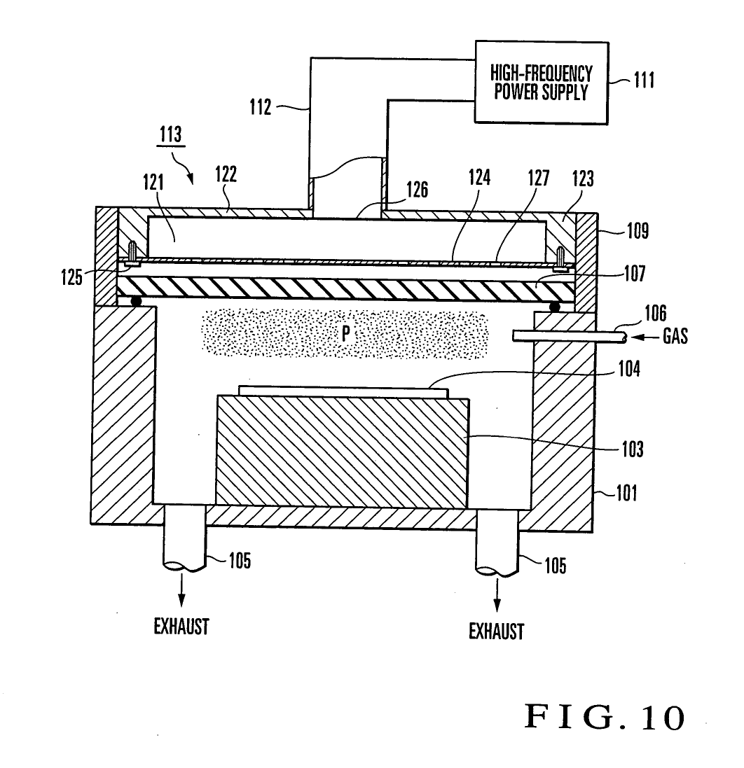

FIG. 8 is a view showing the structure of part of a plasma processing apparatus according to the fifth embodiment of the present invention. In FIG. 8, constituent elements such as a processing vessel 1 are not shown.

The plasma processing apparatus according to this embodiment is provided with a heat transfer member 81 which is present between an antenna surface 24 of an RLSA 13 and a conductive plate 22 and connects them to transfer the heat of the antenna surface 24 to the conductive plate 22. As a whole, the heat transfer member 81 has the same size and shape as those of a radial waveguide 21 of the RLSA 13, but has a hole at a portion corresponding to an opening 26 of the conductive plate 22. Accordingly, the heat transfer member 81 is in contact with the entire area of the conductive plate 22 excluding the opening 26 and the opposing region of the antenna surface 24. The heat transfer member 81 is made of a dielectric material having good heat conductivity, e.g., an alumina ceramic material or boron nitride (BN).

A cooling unit 82 is arranged on the conductive plate 22 of the RLSA 13 to be in contact with the conductive plate 22. The cooling unit 82 can include an electronic refrigerating/heating element such as a Peltier element. Alternatively, a cooling unit may be used in which a flow channel is formed in a plate-like member and a refrigerant such as cooling water is supplied in the flow channel to cool the conductive plate 22.

The heat of the antenna surface 24 of the RLSA 13 is transferred to the conductive plate 22 (or a conductive ring 23) through the heat transfer member 81 and dissipated outside from the conductive plate 22 through the cooling unit 82. When the heat of the antenna surface 24 is dissipated outside in this manner, the antenna surface 24 can be cooled.

As the heat transfer member which transfers the heat of the antenna surface 24 to the conductive plate 22, columnar dielectric columns 83 as shown in FIG. 9 can be used. The plurality of dielectric columns 83 are evenly arranged on the antenna surface 24. When the columnar dielectric columns 83 are used as the heat transfer member, the volume proportion of the heat transfer member in the radial waveguide 21 decreases, so that the influence that the heat transfer member exerts on the high-frequency electromagnetic field propagating in the radial waveguide 21 decreases. When an electronic refrigerating/heating element such as a Peltier element is used as the cooling unit 82, it is arranged immediately above the position where the dielectric columns 81 are connected to the conductive plate 22, so that heat transferred from the antenna surface 24 can be dissipated outside efficiently.

The cooling unit 82 is not always necessary, and the conductive plate 22 can be cooled by spontaneous heat dissipation.

In the above description, the antenna surface 24 of the RLSA 13 is cooled. The present invention is useful in cooling the antenna surface of an antenna in which an antenna element is formed on one surface of a waveguide. For example, the present invention can also be applied to a waveguide slot antenna or a slot antenna in which slots are formed in one of two opposing conductive plates that form a waveguide and power is supplied from the side surface of the waveguide.

As has been described above, according to the embodiments described above, the cooling means is provided for cooling the conductive plate where the antenna element is formed, to suppress a temperature change which is caused by heat generated by the conductive plate. This can prevent the conductive plate from being deformed by heat to change its antenna characteristics. Hence, the distribution of the plasma generated in the processing vessel does not change due to the influence of a change in antenna characteristics, and an object to be processed arranged in the processing vessel can be processed uniformly.

1. A plasma processing apparatus characterized by comprising:
a stage on which an object to be processed is to be placed;
a vessel which houses said stage;
a conductive plate which is arranged to oppose said stage;
an antenna element which is formed on said conductive plate;
a waveguide member which constitutes, together with said conductive plate, a waveguide which guides a high-frequency electromagnetic field to be supplied to said vessel through said antenna element; and
cooling means for cooling said conductive plate.

2. A plasma processing apparatus according to claim 1, characterized in that said cooling means includes
refrigerant supplying means for externally supplying a refrigerant into said waveguide; and
refrigerant discharging means for discharging to outside the refrigerant which has circulated in said waveguide.

3. A plasma processing apparatus according to claim 2, characterized in that
said refrigerant supplying means includes a refrigerant supply channel which opens to said waveguide at a first position, and
said refrigerant discharging means includes a refrigerant discharge channel which opens to said waveguide at a second position separate from the first position.

4. A plasma processing apparatus according to claim 3, characterized in that said refrigerant supplying means and refrigerant discharging means include
a refrigerant flow channel formed by connecting said refrigerant supply channel and refrigerant discharge channel,
refrigerant feeding means, provided to said refrigerant flow channel, for circulating said refrigerant in said refrigerant flow channel and waveguide, and
refrigerant cooling means, provided to said refrigerant flow channel, to cool said refrigerant.

5. A plasma processing apparatus according to claim 2, characterized in that said refrigerant supplying means includes
a pipe line to which said refrigerant is supplied to increase a pressure therein to be higher than that in said waveguide, and
a hole through which interiors of said waveguide and pipe line communicate with each other.

6. A plasma processing apparatus according to claim 2, characterized in that
said refrigerant comprises an inert gas.

7. A plasma processing apparatus according to claim 2, characterized in that
said refrigerant comprises a gas containing an atomized liquid agent.

8. A plasma processing apparatus according to claim 2, characterized in that
said refrigerant comprises a liquid.

9. A plasma processing apparatus according to claim 1, characterized in that
said cooling means includes a heat transfer member which is made of a dielectric and present between and connects said conductive plate and waveguide member to transfer heat of said conductive plate to said waveguide member.

10. A plasma processing apparatus according to claim 9, characterized in that
said heat transfer member has a columnar shape.

11. A plasma processing apparatus according to claim 9, characterized in that
said cooling means further includes waveguide member cooling means for cooling said waveguide member which is heated by heat of said conductive plate.

12. A plasma processing method characterized by comprising the steps of:
guiding a high-frequency electromagnetic field to a waveguide which includes a waveguide member and conductive plate;
supplying the high-frequency electromagnetic field into a vessel through an antenna element formed on the conducive plate to generate a plasma in the vessel and cooling the conductive plate; and
processing an object to be processed arranged in the vessel by using the plasma.
